(19) United States
(12) Patent Application Publication
(10) Pub. No.: US 2023/0378333 A1
(43) Pub. Date: Nov. 23, 2023

(54) SEMICONDUCTOR DEVICE

(71) Applicant: FUJI ELECTRIC CO., LTD., Kanagawa (JP)

(72) Inventors: Tohru SHIRAKAWA, Matsumoto-city (JP); Kaname MITSUZUKA, Matsumoto-city (JP)

(21) Appl. No.: 18/305,386

(22) Filed: Apr. 24, 2023

(30) Foreign Application Priority Data
May 18, 2022 (JP) 2022-081761

(51) Int. Cl. H01L 29/739; H01L 29/06; H01L 29/10

(52) U.S. Cl. CPC H01L 29/7397; H01L 29/0696; H01L 29/1095

(57) ABSTRACT

Provided is a semiconductor device including: a collector region of a second conductivity type, which is provided between a drift region and a lower surface of a semiconductor substrate, in which the collector region includes a first region and a second region having a lower implantation efficiency of carriers with respect to the drift region than the first region, and when an area of the first region and an area of the second region per unit area of the collector region in a top view are respectively represented by S₁ and S₂, the implantation efficiency of the first region is represented by η₁, and the implantation efficiency of the second region is represented by η₂, an average implantation efficiency η_{C} given by an expression below is 0.1 or more and 0.4 or less: η_{C}=(S₁×η₁+S₂×η₂)/(S₁+S₂).

The contents of the following Japanese patent application(s) are incorporated herein by reference:

NO. 2022-081761 filed in JP on May 18, 2022

### BACKGROUND

### 1. Technical Field

The present invention relates to a semiconductor device.

### 2. Related Art

Conventionally, a semiconductor device including an IGBT or the like is known (see, for example, Patent Documents 1 and 2).

### PRIOR ART DOCUMENTS

### Patent Documents

Patent Document 1: Japanese Patent Application Publication No. 2015-023118

Patent Document 2: Japanese Patent Application Publication No. 2018-049866

### BRIEF DESCRIPTION OF THE DRAWINGS

FIG. 1 illustrates a top view showing an example of a semiconductor device 100 according to one embodiment of the present invention.

FIG. 2 is an enlarged view of a region D in FIG. 1.

FIG. 3 illustrates a view showing an example of a cross section e-e in FIG. 2.

FIG. 4A illustrates a view showing an exemplary arrangement of first regions 26 and second regions 28 in a top view.

FIG. 4B illustrates a view showing characteristics of an area S2 of the second region 28 with respect to an area S1 of the first region 26.

FIG. 5 illustrates a view showing an exemplary arrangement of the first region 26 and the second region 28 in a top view.

FIG. 6 illustrates a view showing an example of a cross section a-a in FIG. 1.

FIG. 7 illustrates a view showing another example of the cross section a-a.

FIG. 8 illustrates a view showing an exemplary arrangement of emitter regions 12 and contact regions 15 in a top view.

FIG. 9 illustrates a view showing another example of the cross section a-a.

FIG. 10 illustrates a view showing an exemplary arrangement of the emitter regions 12 and the contact regions 15 in a top view.

FIG. 11 illustrates a view showing an example of a cross section b-b in FIG. 1.

FIG. 12 illustrates a view showing an example of the cross section b-b in FIG. 1.

FIG. 13 illustrates a view showing an example of a net doping concentration distribution on a line c-c in FIG. 3.

FIG. 14 illustrates a view showing another example of the first regions 26 and the second regions 28.

FIG. 15 illustrates a view showing a relationship between a dose amount setting value of a P type impurity implanted into a collector region 22 and a doping concentration variation of the collector region 22.

### DESCRIPTION OF EXEMPLARY EMBODIMENTS

Hereinafter, the invention will be described through embodiments of the invention, but the following embodiments do not limit the present invention according to claims. In addition, not all of the combinations of features described in the embodiments are essential to the solution of the invention.

As used herein, one side in a direction parallel to a depth direction of a semiconductor substrate is referred to as “upper” and the other side is referred to as “lower”. One surface of two principal surfaces of a substrate, a layer, or other member is referred to as an upper surface, and the other surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate a height direction with respect to the ground. Note that a +Z axis direction and a −Z axis direction are directions opposite to each other. When the Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. Further, an axis perpendicular to the upper surface and the lower surface of the semiconductor substrate is referred to as the Z axis. In the present specification, the direction of the Z axis may be referred to as the depth direction. Further, in the present specification, a direction parallel to the upper surface and the lower surface of the semiconductor substrate may be referred to as a horizontal direction, including an X axis direction and a Y axis direction.

A region from a center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of a doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type, or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking polarities of charges into account. As an example, when the donor concentration is ND and the acceptor concentration is NA, the net doping concentration at any position is given as ND-NA. In the present specification, the net doping concentration may be simply referred to as the doping concentration.

The donor has a function of supplying electrons to a semiconductor. The acceptor has a function of receiving electrons from the semiconductor. The donor and the acceptor are not limited to the impurities themselves. For example, a VOH defect which is a combination of a vacancy (V), oxygen (O), and hydrogen (H) existing in the semiconductor functions as the donor that supplies electrons. In the present specification, the VOH defect may be referred to as a hydrogen donor.

In the present specification, bulk donors of the N type are distributed throughout the semiconductor substrate. The bulk donor is a dopant donor substantially uniformly contained in an ingot during the manufacture of the ingot from which the semiconductor substrate is made. The bulk donor of this example is an element other than hydrogen. The dopant of the bulk donor is, for example, phosphorus, antimony, arsenic, selenium, or sulfur, but the present invention is not limited to these. The bulk donor of this example is phosphorus. The bulk donor is also contained in the P type region. The semiconductor substrate may be a wafer cut out from a semiconductor ingot, or may be a chip obtained by singulating the wafer. The semiconductor ingot may be manufactured by any of a Chokralski method (CZ method), a magnetic field applied Chokralski method (MCZ method), or a float zone method (FZ method). The ingot of this example is manufactured by the MCZ method. An oxygen concentration contained in the substrate manufactured by the MCZ method is 1×10¹⁷ to 7×10¹⁷/cm³. The oxygen concentration contained in the substrate manufactured by the FZ method is 1×10¹⁵ to 5×10¹⁶/cm³. When the oxygen concentration is high, hydrogen donors tend to be easily generated. A chemical concentration of a bulk donor distributed throughout the semiconductor substrate may be used for the bulk donor concentration, which may also be a value from 90% to 100% of the chemical concentration. Further, as the semiconductor substrate, a non-doped substrate not containing a dopant such as phosphorus may be used. In that case, the bulk donor concentration (D0) of the non-doped substrate is, for example, 1×10¹⁰/cm³ or more and 5×10¹²/cm³ or less. The bulk donor concentration (D0) of the non-doped substrate is preferably 1×10¹¹/cm³ or more. The bulk donor concentration (D0) of the non-doped substrate is preferably 5×10¹²/cm³ or less. Note that each concentration in the present invention may be a value at room temperature. As the value at room temperature, a value at 300 K (Kelvin) (about 26.9° C.) may be used as an example.

In the present specification, a description of a P+ type or an N+ type means a higher doping concentration than that of the P type or the N type, and a description of a P− type or an N− type means a lower doping concentration than that of the P type or the N type. Further, in the present specification, a description of a P++ type or an N++ type means a higher doping concentration than that of the P+ type or the N+ type. In the present specification, a unit system is the SI base unit system unless otherwise stated in particular. Although a unit of length is represented using cm, it may be converted to meters (m) before calculations.

A chemical concentration in the present specification indicates an atomic density of an impurity measured regardless of an electrical activation state. The chemical concentration can be measured by, for example, secondary ion mass spectrometry (SIMS). The net doping concentration described above can be measured by voltage-capacitance profiling (CV profiling). Further, a carrier concentration measured by a spreading resistance method (SRP method) may be set as the net doping concentration. The carrier concentration measured by the CV profiling or the SRP method may be set as a value in a thermal equilibrium state. Further, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

When a concentration distribution of the donor, acceptor, or net doping has a peak in a region, a value of the peak may be set as the concentration of the donor, acceptor, or net doping in the region. In a case where the concentration of the donor, acceptor, or net doping is substantially uniform in a region, or the like, an average value of the concentration of the donor, acceptor, or net doping in the region may be set as the concentration of the donor, acceptor, or net doping. In the present specification, atoms/cm³ or /cm³ is used to indicate a concentration per unit volume. This unit is used for a concentration of a donor or an acceptor in a semiconductor substrate, or a chemical concentration. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The reduction in carrier mobility occurs when carriers are scattered due to disorder (disorder) of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorus or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

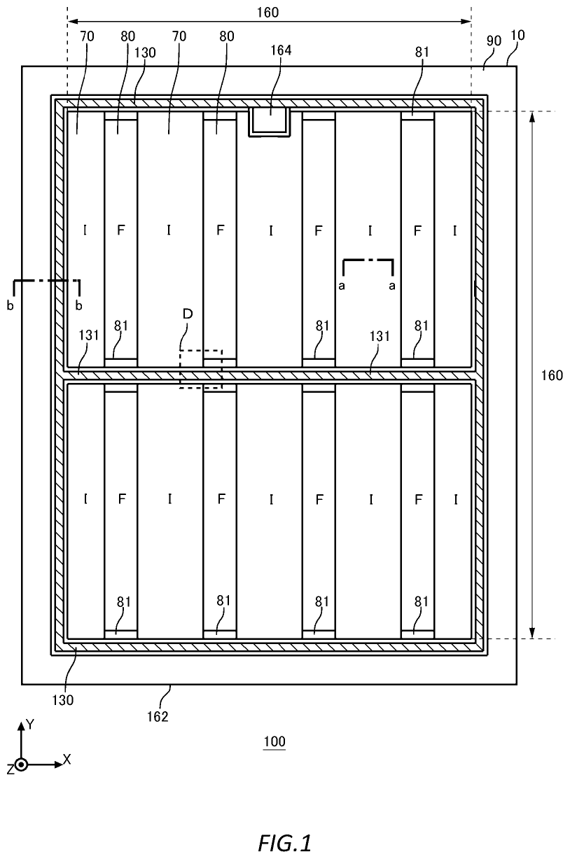

FIG. 1 illustrates a top view showing an example of a semiconductor device 100 according to one embodiment of the present invention. FIG. 1 shows a position at which each member is projected on an upper surface of a semiconductor substrate 10. FIG. 1 shows merely some members of the semiconductor device 100, and omits illustrations of some members.

The semiconductor device 100 includes the semiconductor substrate 10. The semiconductor substrate 10 is a substrate that is formed of a semiconductor material. As an example, the semiconductor substrate 10 is a silicon substrate. The semiconductor substrate 10 has an end side 162 in the top view. When merely referred to as the top view in the present specification, it means that the semiconductor substrate 10 is viewed from an upper surface side. The semiconductor substrate 10 of this example has two sets of end sides 162 opposite to each other in the top view. In FIG. 1, the X axis and the Y axis are parallel to any of the end sides 162. In addition, the Z axis is perpendicular to the upper surface of the semiconductor substrate 10.

The semiconductor substrate 10 is provided with an active portion 160. The active portion 160 is a region where a main current flows in the depth direction between the upper surface and a lower surface of the semiconductor substrate 10 when the semiconductor device 100 operates. An emitter electrode is provided above the active portion 160, but is omitted in FIG. 1. The active portion 160 may refer to a region that overlaps with the emitter electrode in the top view. Further, a region sandwiched by the active portion 160 in the top view may also be included in the active portion 160.

The active portion 160 is provided with a transistor portion 70 including a transistor element such as an IGBT (Insulated Gate Bipolar Transistor). The active portion 160 may further be provided with a diode portion 80 including a diode element such as a freewheeling diode (FWD). In the example of FIG. 1, the transistor portion 70 and the diode portion 80 are alternately arranged along a predetermined array direction (the X axis direction in this example) on the upper surface of the semiconductor substrate 10. The semiconductor device 100 of this example is a reverse-conducting IGBT (RC-IGBT).

In FIG. 1, a region where each of the transistor portions 70 is arranged is indicated by a symbol “I”, and a region where each of the diode portions 80 is arranged is indicated by a symbol F. In the present specification, a direction perpendicular to the array direction in the top view may be referred to as an extending direction (the Y axis direction in FIG. 1). Each of the transistor portions 70 and the diode portions 80 may have a longitudinal length in the extending direction. In other words, the length of each of the transistor portions 70 in the Y axis direction is larger than the width in the X axis direction. Similarly, the length of each of the diode portions 80 in the Y axis direction is larger than the width in the X axis direction. The extending direction of the transistor portion 70 and the diode portion 80, and the longitudinal direction of each trench portion described later may be the same.

Each of the diode portions 80 includes a cathode region of the N+ type in a region in contact with the lower surface of the semiconductor substrate 10. In the present specification, a region where the cathode region is provided is referred to as the diode portion 80. In other words, the diode portion 80 is a region that overlaps with the cathode region in the top view. On the lower surface of the semiconductor substrate 10, a collector region of the P+ type may be provided in a region other than the cathode region. In the present specification, the diode portion 80 may also include an extension region 81 where the diode portion 80 extends to a gate runner described later in the Y axis direction. The collector region is provided on a lower surface of the extension region 81.

The transistor portion 70 has the collector region of the P+ type in a region in contact with the lower surface of the semiconductor substrate 10. Further, in the transistor portion 70, an emitter region of the N type, a base region of the P type, and a gate structure having a gate conductive portion and a gate dielectric film are periodically arranged on the upper surface side of the semiconductor substrate 10.

The semiconductor device 100 may have one or more pads above the semiconductor substrate 10. The semiconductor device 100 of this example has a gate pad 164. The semiconductor device 100 may have a pad such as an anode pad, a cathode pad, and a current detection pad. Each pad is arranged in a region close to the end side 162. The region close to the end side 162 refers to a region between the end side 162 and the emitter electrode in the top view. When the semiconductor device 100 is mounted, each pad may be connected to an external circuit via a wiring such as a wire.

A gate potential is applied to the gate pad 164. The gate pad 164 is electrically connected to a conductive portion of a gate trench portion of the active portion 160. The semiconductor device 100 includes a gate runner that connects the gate pad 164 and the gate trench portion. In FIG. 1, the gate runner is hatched with diagonal lines.

The gate runner of this example has an outer circumferential gate runner 130 and an active-side gate runner 131. The outer circumferential gate runner 130 is arranged between the active portion 160 and the end side 162 of semiconductor substrate 10 in the top view. The outer circumferential gate runner 130 of this example encloses the active portion 160 in the top view. A region enclosed by the outer circumferential gate runner 130 in the top view may be the active portion 160. Further, a well region is formed below the gate runner. The well region is a P type region having a higher concentration than the base region described later, and is formed to a position deeper than the base region from the upper surface of the semiconductor substrate 10. In the top view, the region enclosed by the well region may be the active portion 160.

The outer circumferential gate runner 130 is connected to the gate pad 164. The outer circumferential gate runner 130 is arranged above the semiconductor substrate 10. The outer circumferential gate runner 130 may be a metal wiring containing aluminum or the like.

The active-side gate runner 131 is provided in the active portion 160. Providing the active-side gate runner 131 in the active portion 160 can reduce a variation in wiring length from the gate pad 164 for each region of the semiconductor substrate 10.

The outer circumferential gate runner 130 and the active-side gate runner 131 are connected to the gate trench portion of the active portion 160. The outer circumferential gate runner 130 and the active-side gate runner 131 are arranged above the semiconductor substrate 10. The outer circumferential gate runner 130 and the active-side gate runner 131 may be a wiring formed of a semiconductor such as polysilicon doped with an impurity.

The active-side gate runner 131 may be connected to the outer circumferential gate runner 130. The active-side gate runner 131 of this example is provided extending in the X axis direction so as to cross the active portion 160 from one outer circumferential gate runner 130 to the other outer circumferential gate runner 130 sandwiching the active portion 160, substantially at the center of the Y axis direction. When the active portion 160 is divided by the active-side gate runner 131, the transistor portion 70 and the diode portion 80 may be alternately arranged in the X axis direction in each divided region.

The semiconductor device 100 may include a temperature sensing portion (not shown) that is a PN junction diode formed of polysilicon or the like, and a current detection portion (not shown) that simulates an operation of the transistor portion provided in the active portion 160.

The semiconductor device 100 of this example includes an edge termination structure portion 90 between the active portion 160 and the end side 162 in the top view. The edge termination structure portion 90 of this example is arranged between the outer circumferential gate runner 130 and the end side 162. The edge termination structure portion 90 reduces an electric field strength on the upper surface side of the semiconductor substrate 10. The edge termination structure portion 90 may include at least one of a guard ring, a field plate, or a RESURF annularly provided to enclose the active portion 160.

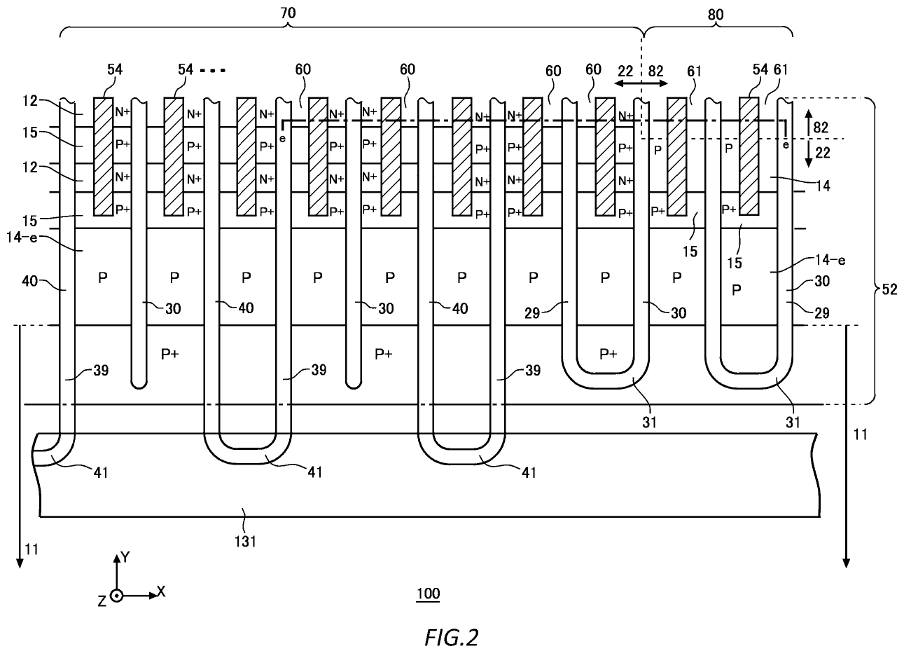

FIG. 2 is an enlarged view of a region D in FIG. 1. The region D is a region including the transistor portion 70, the diode portion 80, and the active-side gate runner 131. The semiconductor device 100 of this example includes a gate trench portion 40, a dummy trench portion 30, a well region 11, an emitter region 12, a base region 14, and a contact region 15 which are provided inside on the upper surface side of the semiconductor substrate 10. The gate trench portion 40 and the dummy trench portion 30 each are an example of the trench portion. Further, the semiconductor device 100 of this example includes an emitter electrode 52 and the active-side gate runner 131 that are provided above the upper surface of the semiconductor substrate 10. The emitter electrode 52 and the active-side gate runner 131 are provided in isolation from each other.

An interlayer dielectric film is provided between the emitter electrode 52 and the active-side gate runner 131, and the upper surface of the semiconductor substrate 10, but the interlayer dielectric film is omitted in FIG. 2. In the interlayer dielectric film of this example, a contact hole 54 is provided passing through the interlayer dielectric film. In FIG. 2, each contact hole 54 is hatched with the diagonal lines.

The emitter electrode 52 is provided above the gate trench portion 40, the dummy trench portion 30, the well region 11, the emitter region 12, the base region 14, and the contact region 15. The emitter electrode 52 is in contact with the emitter region 12, the contact region 15, and the base region 14 on the upper surface of the semiconductor substrate 10, through the contact hole 54. Further, the emitter electrode 52 is connected to a dummy conductive portion in the dummy trench portion 30 through the contact hole provided in the interlayer dielectric film. The emitter electrode 52 may be connected to the dummy conductive portion of the dummy trench portion 30 at an edge of the dummy trench portion 30 in the Y axis direction. The dummy conductive portion of the dummy trench portion 30 does not need to be connected to the emitter electrode 52 and the gate conductive portion, and may be controlled to be set at a potential different from the potential of the emitter electrode 52 and the potential of the gate conductive portion.

The active-side gate runner 131 is connected to the gate trench portion 40 through the contact hole provided in the interlayer dielectric film. The active-side gate runner 131 may be connected to a gate conductive portion of the gate trench portion 40 at an edge portion 41 of the gate trench portion 40 in the Y axis direction. The active-side gate runner 131 is not connected to the dummy conductive portion in the dummy trench portion 30.

The emitter electrode 52 is formed of a material including metal. FIG. 2 shows a range where the emitter electrode 52 is provided. For example, at least a part of a region of the emitter electrode 52 is formed of aluminum or an aluminum-silicon alloy, for example, a metal alloy such as AlSi or AlSiCu. The emitter electrode 52 may have a barrier metal formed of titanium, a titanium compound, or the like below a region formed of aluminum or the like. Further, a plug, which is formed by embedding tungsten or the like so as to be in contact with the barrier metal and aluminum or the like, may be included in the contact hole.

The well region 11 is provided overlapping the active-side gate runner 131. The well region 11 is provided so as to extend with a predetermined width even in a range not overlapping the active-side gate runner 131. The well region 11 of this example is provided away from an end of the contact hole 54 in the Y axis direction toward the active-side gate runner 131 side. The well region 11 is a second conductivity type region having a higher doping concentration than the base region 14. The base region 14 of this example is a P type, and the well region 11 is a P+ type.

Each of the transistor portion 70 and the diode portion 80 includes a plurality of trench portions arranged in the array direction. In the transistor portion 70 of this example, one or more gate trench portions 40 and one or more dummy trench portions 30 are alternately provided along the array direction. In the diode portion 80 of this example, the plurality of dummy trench portions 30 are provided along the array direction. In the diode portion 80 of this example, the gate trench portion 40 is not provided.

The gate trench portion 40 of this example may have two linear portions 39 extending along the extending direction perpendicular to the array direction (portions of a trench that are linear along the extending direction), and the edge portion 41 connecting the two linear portions 39. The extending direction in FIG. 2 is the Y axis direction.

At least a part of the edge portion 41 is preferably provided in a curved shape in a top view. By connecting between end portions of the two linear portions 39 in the Y axis direction by the edge portion 41, it is possible to reduce the electric field strength at the end portions of the linear portions 39.

In the transistor portion 70, the dummy trench portions 30 are provided between the respective linear portions 39 of the gate trench portions 40. Between the respective linear portions 39, one dummy trench portion 30 may be provided, or a plurality of dummy trench portions 30 may be provided. The dummy trench portion 30 may have a linear shape extending in the extending direction, or may have linear portions 29 and an edge portion 31 similar to the gate trench portion 40. The semiconductor device 100 shown in FIG. 2 includes both of the linear dummy trench portion 30 having no edge portion 31, and the dummy trench portion 30 having the edge portion 31.

A diffusion depth of the well region 11 may be deeper than the depth of the gate trench portion 40 and the dummy trench portion 30. The end portions of the gate trench portion 40 and the dummy trench portion 30 in the Y axis direction are provided in the well region 11 in a top view. In other words, the bottom of each trench portion in the depth direction is covered with the well region 11 at the end portion of each trench portion in the Y axis direction. With this configuration, the electric field strength at the bottom of each trench portion can be reduced.

A mesa portion is provided between the respective trench portions in the array direction. The mesa portion refers to a region sandwiched between the trench portions inside the semiconductor substrate 10. As an example, an upper end of the mesa portion is the upper surface of the semiconductor substrate 10. The depth position of the lower end of the mesa portion is the same as the depth position of the lower end of the trench portion. The mesa portion of this example is provided extending in the extending direction (the Y axis direction) along the trench, on the upper surface of the semiconductor substrate 10. In this example, a mesa portion 60 is provided in the transistor portion 70, and a mesa portion 61 is provided in the diode portion 80. In the case of simply mentioning “mesa portion” in the present specification, the portion refers to each of the mesa portion 60 and the mesa portion 61.

Each mesa portion is provided with the base region 14. In the mesa portion, a region arranged closest to the active-side gate runner 131, in the base region 14 exposed on the upper surface of the semiconductor substrate 10, is to be a base region 14-e. While FIG. 2 shows the base region 14-e arranged at one end portion of each mesa portion in the extending direction, the base region 14-e is also arranged at the other end portion of each mesa portion. In each mesa portion, at least one of the emitter region 12 of the first conductivity type or the contact region 15 of the second conductivity type may be provided in the region sandwiched between the base regions 14-e in a top view. The emitter region 12 of this example is an N+ type, and the contact region 15 is a P+type. The emitter region 12 and the contact region 15 may be provided between the base region 14 and the upper surface of the semiconductor substrate 10 in the depth direction.

The mesa portion 60 of the transistor portion 70 has the emitter region 12 in contact with the upper surface (that is, exposed on the upper surface) of the semiconductor substrate 10. The emitter region 12 is provided in contact with the gate trench portion 40. The mesa portion 60 in contact with the gate trench portion 40 may be provided with the contact region 15 exposed on the upper surface of the semiconductor substrate 10.

Each of the contact region 15 and the emitter region 12 in the mesa portion 60 is provided from one trench portion to the other trench portion in the X axis direction. As an example, the contact region 15 and the emitter region 12 in the mesa portion 60 are alternately arranged along the extending direction of the trench portion (the Y axis direction).

In another example, the contact region 15 and the emitter region 12 in the mesa portion 60 may be provided in a stripe shape along the extending direction of the trench portion (the Y axis direction). For example, the emitter region 12 is provided in a region in contact with the trench portion, and the contact region 15 is provided in a region sandwiched between the emitter regions 12.

The mesa portion 61 of the diode portion 80 is not provided with the emitter region 12. The base region 14 and the contact region 15 may be provided on an upper surface of the mesa portion 61. In the region sandwiched between the base regions 14-e on the upper surface of the mesa portion 61, the contact region 15 may be provided in contact with each base region 14-e. The base region 14 may be provided in a region sandwiched between the contact regions 15 on the upper surface of the mesa portion 61. The base region 14 may be arranged in the entire region sandwiched between the contact regions 15.

The contact hole 54 is provided above each mesa portion. The contact hole 54 is arranged in the region sandwiched between the base regions 14-e. The contact hole 54 of this example is provided above the respective regions of the contact region 15, the base region 14, and the emitter region 12. The contact hole 54 is not provided in regions corresponding to the base region 14-e and the well region 11. The contact hole 54 may be arranged at the center of the mesa portion 60 in the array direction (the X axis direction).

In the diode portion 80, a cathode region 82 of the N+ type is provided in a region in direct contact with the lower surface of the semiconductor substrate 10. On the lower surface of the semiconductor substrate 10, a collector region 22 of the P+ type may be provided in a region where the cathode region 82 is not provided. The cathode region 82 and the collector region 22 are provided between the lower surface 23 of the semiconductor substrate 10 and a buffer region 20. In FIG. 2, a boundary between the cathode region 82 and the collector region 22 is indicated by a dotted line.

The cathode region 82 is arranged separately from the well region 11 in the Y axis direction. With this configuration, the distance between the P type region (the well region 11) having a relatively high doping concentration and formed up to the deep position, and the cathode region 82 is ensured, so that the breakdown voltage can be improved. The end portion of the cathode region 82 of this example in the Y axis direction is arranged farther away from the well region 11 than the end portion of the contact hole 54 in the Y axis direction. In another example, the end portion of the cathode region 82 in the Y axis direction may be arranged between the well region 11 and the contact hole 54.

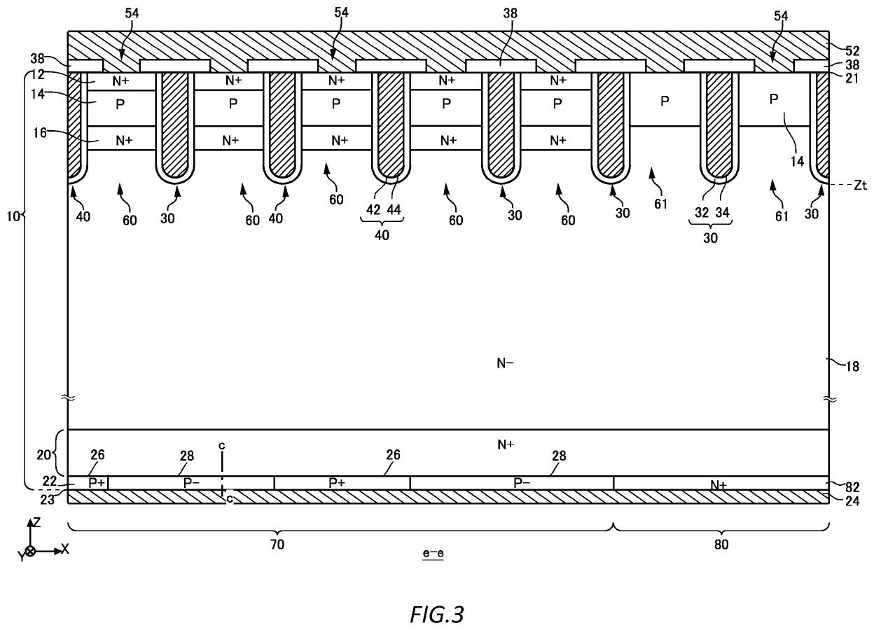

FIG. 3 illustrates a view showing an example of a cross section e-e in FIG. 2. The cross section e-e is an XZ plane passing through the emitter region 12 and the cathode region 82. The semiconductor device 100 of this example includes the semiconductor substrate 10, the interlayer dielectric film 38, the emitter electrode 52, and the collector electrode 24 in the cross section.

The interlayer dielectric film 38 is provided on the upper surface of the semiconductor substrate 10. The interlayer dielectric film 38 is a film including at least one layer of a dielectric film such as silicate glass to which an impurity such as boron or phosphorus is added, a thermal oxide film, and other dielectric films. The interlayer dielectric film 38 is provided with the contact hole 54 described in FIG. 2.

The emitter electrode 52 is provided above the interlayer dielectric film 38. The emitter electrode 52 is in contact with the upper surface 21 of the semiconductor substrate 10 through the contact hole 54 of the interlayer dielectric film 38. The collector electrode 24 is provided on the lower surface 23 of the semiconductor substrate 10. The emitter electrode 52 and the collector electrode 24 are formed of a metal material such as aluminum. In the present specification, the direction in which the emitter electrode 52 is connected to the collector electrode 24 (the Z axis direction) is referred to as a depth direction.

The semiconductor substrate 10 has an N type or N− type drift region 18. The drift region 18 is provided in each of the transistor portion 70 and the diode portion 80.

In the mesa portion 60 of the transistor portion 70, the emitter region 12 of the N+ type and the base region 14 of the P type are provided in order from the upper surface 21 side of the semiconductor substrate 10. The drift region 18 is provided below the base region 14. The mesa portion 60 may be provided with an accumulation region 16 of the N+ type. The accumulation region 16 is arranged between the base region 14 and the drift region 18. The accumulation region 16 is an N+ type region having a higher doping concentration than the drift region 18. By providing the accumulation region 16 having the high concentration between the drift region 18 and the base region 14, it is possible to improve a carrier injection enhancement effect (IE effect) and reduce an on-voltage. The accumulation region 16 may be provided to cover a whole lower surface of the base region 14 in each mesa portion 60. The accumulation region 16 may also be provided in each mesa portion 61 of the diode portion 80, or does not need to be provided.

The emitter region 12 is exposed on the upper surface 21 of the semiconductor substrate 10 and is provided in contact with the gate trench portion 40. The emitter region 12 may be in contact with the trench portions on both sides of the mesa portion 60. The emitter region 12 has a higher doping concentration than the drift region 18.

The base region 14 is provided below the emitter region 12. The base region 14 of this example is provided in contact with the emitter region 12. The base region 14 may be in contact with the trench portions on both sides of the mesa portion 60.

The mesa portion 61 of the diode portion 80 is provided with the P type base region 14 in contact with the upper surface 21 of the semiconductor substrate 10. The drift region 18 is provided below the base region 14. The base region 14 of the diode portion 80 may be referred to as an anode region.

In each of the transistor portion 70 and the diode portion 80, an N+ type buffer region 20 may be provided below the drift region 18. The doping concentration of the buffer region 20 is higher than the doping concentration of the drift region 18. The buffer region 20 may have a concentration peak having a higher doping concentration than the drift region 18. The doping concentration of the concentration peak indicates a doping concentration at the local maximum of the concentration peak. Further, as the doping concentration of the drift region 18, an average value of doping concentrations in the region where the doping concentration distribution is substantially flat may be used.

The buffer region 20 may have two or more concentration peaks in the depth direction (the Z axis direction) of the semiconductor substrate 10. The concentration peak of the buffer region 20 may be provided at the same depth position as, for example, a chemical concentration peak of hydrogen (proton) or phosphorus. The buffer region 20 may function as a field stopper layer which prevents a depletion layer expanding from the lower end of the base region 14 from reaching the collector region 22 of the P+ type and the cathode region 82 of the N+ type.

In the transistor portion 70, the collector region 22 of the P+ type is provided below the buffer region 20. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

Below the buffer region 20 in the diode portion 80, the cathode region 82 of the N+ type is provided. A donor concentration of the cathode region 82 is higher than a donor concentration of the drift region 18. A donor of the cathode region 82 is, for example, hydrogen or phosphorus. Note that an element serving as a donor and an acceptor in each region is not limited to the example described above. The collector region 22 and the cathode region 82 are exposed on the lower surface 23 of the semiconductor substrate 10 and are connected to the collector electrode 24. The collector electrode 24 may be in contact with the entire lower surface 23 of the semiconductor substrate 10. The emitter electrode 52 and the collector electrode 24 are formed of a metal material such as aluminum.

One or more gate trench portions 40 and one or more dummy trench portions 30 are provided on the upper surface 21 side of the semiconductor substrate 10. Each trench portion passes through the base region 14 from the upper surface 21 of the semiconductor substrate 10, and is provided to below the base region 14. In a region where at least any of the emitter region 12, the contact region 15, or the accumulation region is provided, each trench portion also passes through the doping regions of these. The configuration of the trench portion penetrating the doping region is not limited to the one manufactured in the order of forming the doping region and then forming the trench portion. The configuration of the trench portion penetrating the doping region also includes a configuration of the doping region being formed between the trench portions after forming the trench portion.

As described above, the transistor portion 70 is provided with the gate trench portion 40 and the dummy trench portion 30. In the diode portion 80, the dummy trench portion 30 is provided, and the gate trench portion 40 is not provided. The boundary in the X axis direction between the diode portion 80 and the transistor portion 70 in this example is the boundary between the cathode region 82 and the collector region 22.

The gate trench portion 40 includes a gate trench provided in the upper surface 21 of the semiconductor substrate 10, a gate dielectric film 42, and a gate conductive portion 44. The gate dielectric film 42 is provided to cover the inner wall of the gate trench. The gate dielectric film 42 may be formed by oxidizing or nitriding a semiconductor on the inner wall of the gate trench. The gate conductive portion 44 is provided inside from the gate dielectric film 42 in the gate trench. That is, the gate dielectric film 42 insulates the gate conductive portion 44 from the semiconductor substrate 10. The gate conductive portion 44 is formed of a conductive material such as polysilicon.

The gate conductive portion 44 may be provided longer than the base region 14 in the depth direction. The gate trench portion 40 in the cross section is covered by the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as the gate trench portions 40 in the cross section. The dummy trench portion 30 includes a dummy trench provided in the upper surface 21 of the semiconductor substrate 10, a dummy dielectric film 32, and a dummy conductive portion 34. The dummy conductive portion 34 is electrically connected to the emitter electrode 52. The dummy dielectric film 32 is provided covering an inner wall of the dummy trench. The dummy conductive portion 34 is provided in the dummy trench, and is provided inside the dummy dielectric film 32. The dummy dielectric film 32 insulates the dummy conductive portion 34 from the semiconductor substrate 10. The dummy conductive portion 34 may be formed of the same material as the gate conductive portion 44. For example, the dummy conductive portion 34 is formed of a conductive material such as polysilicon. The dummy conductive portion 34 may have the same length as the gate conductive portion 44 in the depth direction.

The gate trench portion 40 and the dummy trench portion 30 of this example are covered with the interlayer dielectric film 38 on the upper surface 21 of the semiconductor substrate 10. Note that the bottoms of the dummy trench portion 30 and the gate trench portion 40 may be formed in a curved-surface shape (a curved shape in the cross section) convexly downward. In the present specification, a depth position of a lower end of the gate trench portion 40 is set as Zt.

In the semiconductor device 100, a switching loss is preferably low. Especially when the semiconductor device 100 is used in a high-speed operation product having an operating frequency of 20 kHz or more, the switching loss of the semiconductor device 100 may become a dominant loss in the product. Thus, if the turn-off loss Eoff of the semiconductor device 100 is low, for example, the product loss can be lowered.

If an implantation efficiency of carriers of the collector region 22 is low, the turn-off loss Eoff can be made small. On the other hand, if the implantation efficiency of the collector region 22 is low, a ratio of a variation to a design value of the implantation efficiency of the collector region 22 becomes large, and thus a variation in characteristics among individual semiconductor devices 100 or lots becomes large.

For example, although the implantation efficiency can be made low by lowering a doping concentration of the collector region 22, a ratio of a variation to a design value of the doping concentration of the collector region 22 becomes large. In such a case, a variation in sheet resistance of the collector region 22 becomes large. When the variation in sheet resistance of the collector region 22 becomes large, variations in on-voltage and latch-up withstand capability of the semiconductor device 100, and the like become large. Moreover, in a circuit which uses a plurality of semiconductor devices 100 in parallel, if the on-voltages of the semiconductor devices 100 vary, currents may get crowded in a particular device to thus lower the withstand capability of the circuit.

The collector region 22 of this example includes a first region 26 and a second region 28. The first region 26 and the second region 28 of this example are arranged next to each other in the XY plane. Each of the first region 26 and the second region 28 is exposed on the lower surface 23 of the semiconductor substrate 10. Further, an upper surface of each of the first region 26 and the second region 28 is in contact with an N type region. Although the upper surface of each of the first region 26 and the second region 28 is in contact with the buffer region 20 in this example, the upper surface may alternatively be in contact with the drift region 18.

The second region 28 has a lower implantation efficiency of carriers (holes in this example) with respect to the drift region 18 than the first region 26. The implantation efficiency is as follows. For example, a current density of holes is represented by Jₚ, and a current density of electrons is represented by Jₙ. The implantation efficiency of the collector region 22 is a ratio of a current density of minority carriers to a total current density. In this example, since the conductivity type of the drift region 18 is the N type and the conductivity type of the collector region 22 is the P type, the minority carriers of the drift region 18 are holes. In this case, the implantation efficiency in the collector region 22 can be defined using Expression (1).

Jₚ/(Jₚ+Jₙ) Expression (1)

Note that the implantation efficiency is an efficiency in the electrode such as the collector electrode 24 or the emitter electrode 52, but since the minority carriers are implanted from the collector region 22 in this example, the implantation efficiency may refer to the implantation efficiency in the collector region 22.

Provision of the second region 28 having a relatively low implantation efficiency can lower an overall implantation efficiency of the collector region 22. Accordingly, the turn-off loss Eoff of the semiconductor device 100 can be reduced. Moreover, since the implantation efficiency of the first region 26 is relatively large, a variation in the implantation efficiency of the first region 26 can be made small. Regarding the implantation efficiency of the collector region 22, since the implantation efficiency of the first region 26 becomes dominant, a variation in the overall implantation efficiency of the collector region 22 can be suppressed by making a variation in the implantation efficiency of the first region 26 small.

The second region 28 of this example has a lower doping concentration than the first region 26. A maximum value of doping concentrations in each region may be used as the doping concentration of each region. As shown in Expression (1), by reducing the doping concentration of the second region 28, the implantation efficiency of the second region 28 can be reduced. In this example, thicknesses of the first region 26 and the second region 28 in the Z axis direction may be the same. The thickness of the first region 26 in the Z axis direction may be larger than that of the second region 28. The thickness of the first region 26 may be 1.5 times or more of the thickness of the second region 28. The thickness of the first region 26 may be 2 times or less of the thickness of the second region 28.

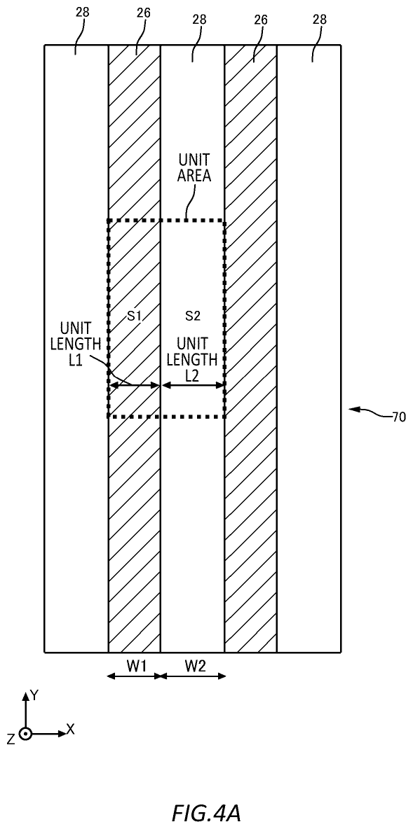

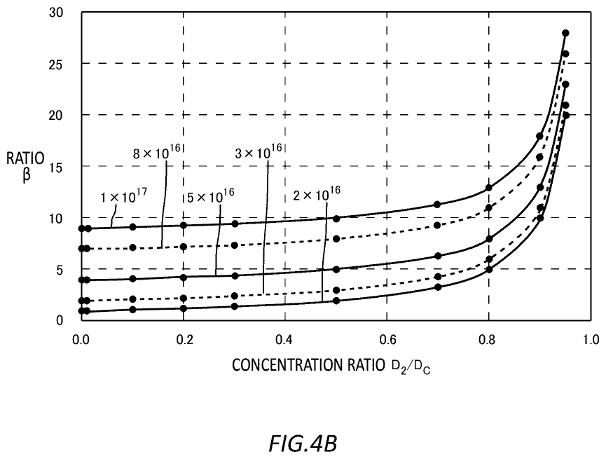

FIG. 4A illustrates a view showing an exemplary arrangement of the first regions 26 and the second regions 28 in a top view. FIG. 4A shows a part of the transistor portion 70. An area of the first region 26 and an area of the second region 28 per unit area of the collector region 22 are respectively represented by S1 and S2. Although the unit area in FIG. 4A is a part of the collector region 22, the unit area may be the entire collector region 22. In this case, a total area of the first regions 26 and a total area of the second regions 28 in the semiconductor device 100 may be respectively represented by S1 and S2.

With the implantation efficiency of the first region 26 being represented by η₁ and the implantation efficiency of the second region 28 being represented by η₂ (η₁>η₂), an average implantation efficiency η_{C} is defined using Expression (2).

η_{C}=(S₁×η₁+S₂×η₂)/(S₁+S₂) Expression (2)

The average implantation efficiency η_{C} is 0.1 or more and 0.4 or less. Accordingly, the average implantation efficiency η_{C} of the semiconductor device 100 can be sufficiently lowered to reduce the turn-off loss. The average implantation efficiency η_{C} may be 0.15 or more, or may be 0.2 or more. The average implantation efficiency η_{C} may be 0.35 or less, or may be 0.3 or less. The implantation efficiency is a current density of minority carriers with respect to the total current density as described above. In this example, the implantation efficiency is a current density of holes with respect to the total current density. In a conduction state, excessive minority carriers and majority carriers are accumulated in the drift region 18, and thus a conductivity modulation occurs. When the ratio of the current density of minority carriers is within the above-described range, the concentration of the minority carriers on the collector region 22 side, that are accumulated in the drift region 18, becomes low, with the result that the concentration of minority carriers on the emitter region 12 side can be made relatively high. Accordingly, the turn-off loss can be reduced. When the average implantation efficiency η_{C} is 0.5 or more, the turn-off loss relatively increases. Therefore, the average implantation efficiency η_{C} may be at least 0.5 or less.

The implantation efficiency η₁ may be 0.5 or more. Accordingly, the variation in the implantation efficiency η₁ can be suppressed. The implantation efficiency η₂ may be 0.3 or less. Accordingly, the average implantation efficiency η_{C} can be made small, to thus reduce the switching loss of the semiconductor device 100. The implantation efficiency η₁ may be 1.2 times or more, 1.5 times or more, 2 times or more, or 3 times or more of the implantation efficiency η₂.

The area S1 of the first region 26 may be the same as or different from the area S2 of the second region 28. The area S1 may be smaller than the area S2. Accordingly, the average implantation efficiency η_{C} and the average doping concentration D_{C} are made small so that it becomes easy to reduce the turn-off loss. The area S1 may be 80% or less or 50% or less of the area S2.

With the doping concentration of the collector region 22 in the first region 26 being represented by D₁ and the doping concentration of the collector region 22 in the second region 28 being represented by D₂ (D₁>D₂), the average doping concentration D_{C} is defined using Expression (3).

D_{C}=(S₁×D₁+S₂×D₂)/(S₁+S₂) Expression (3)

The average doping concentration D_{C} may be 1×10¹⁵/cm³ or more and 1×10¹⁸/cm³ or less. Accordingly, the average doping concentration D_{C} of the collector region 22 can be sufficiently lowered to thus reduce the turn-off loss. The average doping concentration D_{C} may be 5×10¹⁵/cm³ or more, or may be 1×10¹⁶/cm³ or more. The average doping concentration D_{C} may be 5×10¹⁷/cm³ or less, or may be 1×10¹⁷/cm³ or less.

The doping concentration D₁ may be 1×10¹⁶/cm³ or more, 1×10¹⁷/cm³ or more, or 1×10¹⁸/cm³ or more. Accordingly, the variation in the doping concentration D₁ can be suppressed. The doping concentration D₁ may be 1×10²¹/cm³ or less, 1×10²⁰/cm³ or less, or 1×10¹⁹/cm³ or less.

The doping concentration D₂ is lower than the average doping concentration D_{C}. The doping concentration D₂ may be 1×10¹⁷/cm³ or less, 5×10¹⁹ cm ⁻³ or less, 1×10¹⁶/cm³ or less, or 5×10¹⁵/cm³ or less. Accordingly, the average doping concentration D_{C} can be made small to thus reduce the switching loss of the semiconductor device 100. The doping concentration D₂ may be equal to or larger than the concentration of a dopant of the semiconductor substrate 10, or may be equal to or larger than the doping concentration of the drift region 18. The doping concentration D₂may be 1×10¹⁴/cm³ or more or 1×10¹⁵/cm³ or more. Accordingly, a contact resistance with the collector electrode 24 can be made small. The doping concentration D₁ may be 2 times or more, 3 times or more, 5 times or more, 10 times or more, 30 times or more, 50 times or more, or 100 times or more of the doping concentration D₂.

The semiconductor device 100 may satisfy at least one of Expression (2) or Expression (3). Accordingly, the turn-off loss can be reduced while suppressing the variation in characteristics. The semiconductor device 100 may satisfy both Expression (2) and Expression (3).

As shown in FIG. 4A, the first regions 26 and the second regions 28 may be arranged in a striped pattern having a longitudinal length in the Y axis direction. The lengths of the first region 26 and the second region 28 in the Y axis direction may be the same or may be different. The first region 26 and the second region 28 of this example are arranged alternately in the X axis direction. A width W1 of the first region 26 in the X axis direction may be the same as or different from a width W2 of the second region 28 in the X axis direction. The width W1 may be smaller than the width W2. Accordingly, the average implantation efficiency η_{C} and the average doping concentration D_{C} are made small so that it becomes easy to reduce the turn-off loss. The width W1 may be 80% or less or 50% or less of the width W2.

FIG. 4B illustrates a view showing characteristics of the area S2 of the second region 28 with respect to the area S1 of the first region 26. FIG. 4B shows characteristics in five cases where the doping concentration D₁ of the first region 26 is 1×10¹⁷/cm³, 8×10¹⁶/cm³, 5×10¹⁶/cm³, 3×10¹⁶/cm³, and 2×10¹⁶/cm³. The doping concentration D₁ in the first region 26 of the collector region 22 may be higher than the average doping concentration D_{C}. The average doping concentration D_{C} may be higher than the doping concentration D₂ of the collector region 22 in the second region 28. A ratio of the area S2 of the second region 28 to the area S1 of the first region 26 in the collector region 22 is represented by α. The ratio α is given by the following expression.

α=S₂/S₁ Expression (4)

Herein, the ratio β is defined by the following expression.

β=(D₁/D_{C}−1)+D₂/(D_{C}−D₂) Expression (5)

When the doping concentration of the first region 26 is represented by D₁ and the doping concentration of the second region 28 is represented by D₂, the ratio β is an index with which it is possible to estimate how many times or more of the area S1 of the first region 26 the area S2 of the second region 28 should be to obtain a desired average doping concentration D_{C}. The ratio α may be equal to or larger than the ratio β.

The first term on the right side of Expression (5) is a term indicating at least how many times of the area S1 of the first region 26 the area S2 of the second region 28 is to be set to. The second term on the right side is a correction term corresponding to the doping concentration D₂ of the second region 28. When the doping concentration D₂ of the second region 28 is sufficiently smaller than the doping concentration D₁ of the first region 26, the second term becomes substantially 0. As the doping concentration D₂ of the second region 28 takes a value closer to the doping concentration D₁ of the first region 26, the area S2 of the second region 28 needs to be set larger for obtaining a target average doping concentration D_{C}.

As shown in FIG. 4B, if the doping concentration D₂ of the second region 28 is sufficiently smaller than the average doping concentration D_{C}, the ratio β becomes stable substantially without depending on the doping concentration D₁ of the first region 26. With the stable ratio β, a fluctuation or variation in the average doping concentration D_{C} is suppressed, and the on-voltage becomes stable. The doping concentration D₂ of the second region 28 may be 0.8 times or less, 0.6 times or less, 0.4 times or less, 0.2 times or less, or 0.1 times or less of the average doping concentration D_{C}. The doping concentration D₂ of the second region 28 may substantially be 0 times the average doping concentration D_{C}. For example, the doping concentration D₂ of the second region 28 may be 10⁻⁵ times or more, 10⁻⁴ times or more, 0.001 times or more, 0.01 times or more, or 0.1 times or more of the average doping concentration D_{C}.

The doping concentration D₁ of the first region 26 may be equal to or larger than the average doping concentration D_{C}, or may be 1.5 times or more, 2 times or more, or 3 times or more of the average doping concentration D_{C}. The doping concentration D₁ of the first region 26 may be 100 times or less, 30 times or less, 10 times or less, or 5 times or less of the average doping concentration D_{C}.

Herein, the average doping concentration D_{C} may be obtained by Expression (3) in the unit area as shown in FIG. 4A. When the first region 26 and the second region 28 are distributed in a striped pattern, the unit length L1 of the first region 26 in a distribution direction (the X axis direction in FIG. 4A) may be substituted for S1 in Expression (3), and the unit length L2 of the second region 28 may be substituted for S2 in Expression (3) for the calculation.

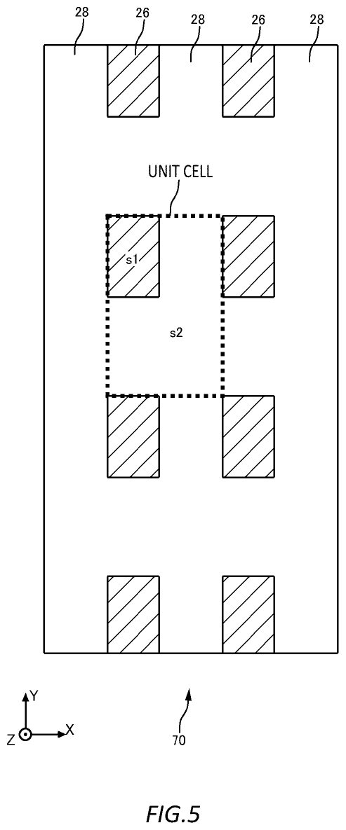

FIG. 5 illustrates a view showing an exemplary arrangement of the first region 26 and the second region 28 in a top view. This example differs from the example shown in FIG. 4A in that the first regions 26 are arranged discretely in the Y axis direction. Other structures are similar to those of the example shown in FIG. 4A. The first region 26 and the second region 28 of this example have a configuration in which the collector region 22 is regularly lined with a unit cell (or a unit lattice) indicated by a dotted line. The average doping concentration D_{C} of this example may be obtained by Expression (3). With an area of the first region 26 in the unit cell being represented by s1 and an area of the second region 28 in the unit cell being represented by s2, the area S1 of the first region 26 in Expression (3) may be substituted by s1, and the area S2 of the second region 28 may be substituted by s2 for the calculation.

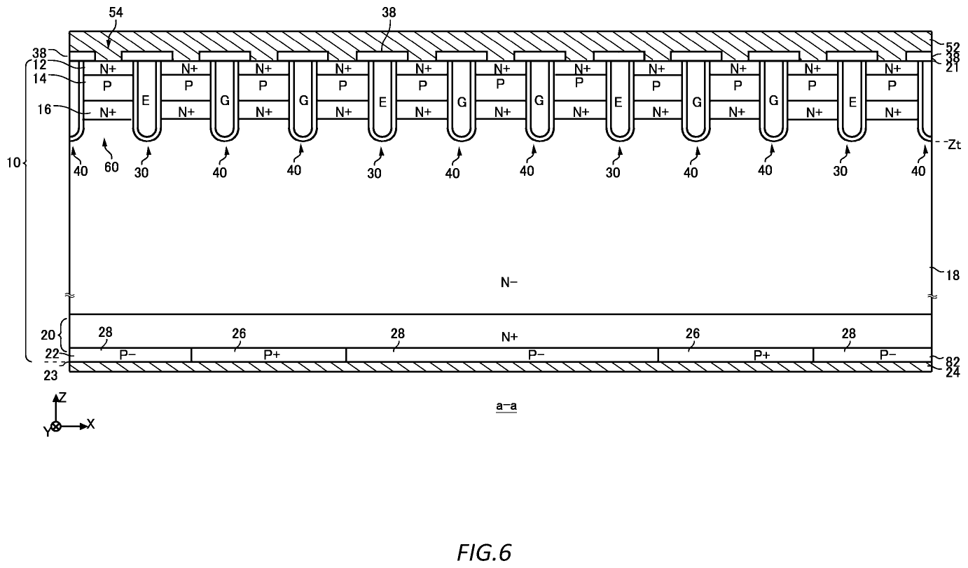

FIG. 6 illustrates a view showing an example of a cross section a-a in FIG. 1. The cross section a-a is an XZ plane that passes through the transistor portion 70. FIG. 6 shows an exemplary arrangement of the first region 26 and the second region 28 in the X axis direction. Structures other than the first region 26 and the second region 28 are similar to those of the example described in FIGS. 1 to 5.

In this example, at least one first region 26 is provided at a position overlapping the gate trench portion 40. All of the first regions 26 may respectively be provided at positions overlapping the gate trench portions 40. The first region 26 overlapping the gate trench portion 40 means that at least one gate trench portion 40 is arranged within a range where the first region 26 is provided in the X axis direction. The first region 26 may also overlap with the dummy trench portion 30. By arranging the first region 26 below the gate trench portion 40, a carrier density below the gate structure can be increased to thus reduce the on-voltage. The number of gate trench portions 40 to be arranged above one first region 26 may be larger than the number of gate trench portions 40 to be arranged above one second region 28. Accordingly, an overall on-voltage of the transistor portion 70 can be reduced. The number of gate trench portions 40 to be arranged above one first region 26 may be the same as or smaller than the number of gate trench portions 40 to be arranged above one second region 28.

As shown in FIG. 6, the second region 28 may be provided below at least one gate trench portion 40. The second region 28 may be provided below each dummy trench portion 30. The second region 28 may be provided below all of the dummy trench portions 30, or the first region 26 may be provided below at least one dummy trench portion 30.

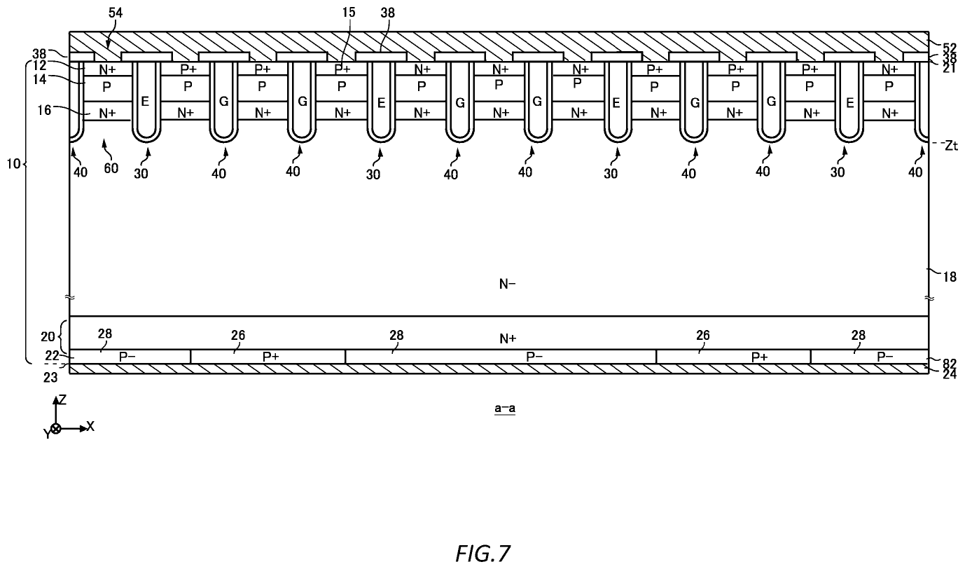

FIG. 7 illustrates a view showing another example of the cross section a-a. In this example, the arrangement of the contact regions 15 on the upper surface 21 of the semiconductor substrate 10 differs from that of the example shown in FIG. 6. Other structures are similar to those of the example shown in FIG. 6. The contact region 15 is a P+ type region which is provided in contact with the upper surface 21 of the semiconductor substrate 10 and has a higher doping concentration than the base region 14.

Either the emitter region 12 or the contact region 15 is exposed on the upper surface of the mesa portion 60 of this example. In this example, more contact regions 15 than the second regions 28 are arranged with respect to the first regions 26. Accordingly, it becomes easy to extract holes implanted from the first region 26 via the contact region 15, and thus a reduction of the latch-up withstand capability can be suppressed.

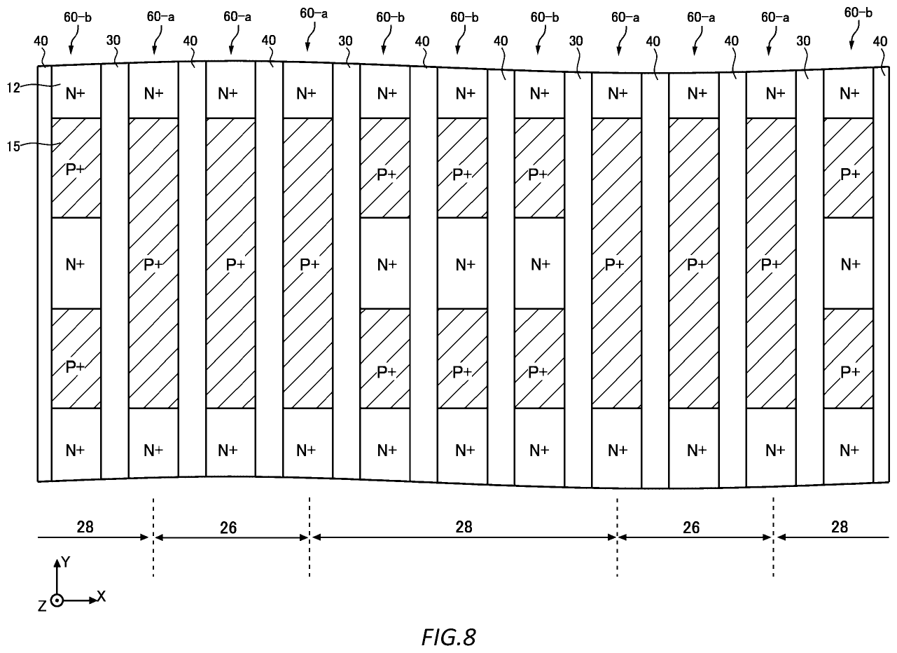

FIG. 8 illustrates a view showing an exemplary arrangement of the emitter regions 12 and the contact regions 15 in a top view. In FIG. 8, the contact regions 15 are hatched with diagonal lines. On the upper surface of each mesa portion 60 of this example, the emitter region 12 and the contact region 15 are arranged alternately in the Y axis direction. A ratio S_{C}/S_{R} of an area S_{C} of the contact regions 15 exposed on the upper surface 21 of the semiconductor substrate 10 to a unit area S_{R} is given as a contact area ratio. The unit area S_{R} may be an area of the entire upper surface of one mesa portion 60. A contact area ratio R1 of the first region 26 may be higher than a contact area ratio R2 of the second region 28. The contact area ratio of each region may be a contact area ratio of a region overlapping each region in a top view. Accordingly, a resistance of a path through which holes implanted from the first region 26 are extracted to the emitter electrode 52 can be lowered, and latch-up can be suppressed. The contact area ratio R1 may be 1.2 times or more, 1.5 times or more, or 2 times or more of the contact area ratio R2.

In this example, the length of one contact region 15 in the Y axis direction in the first region 26 is larger than the length of one contact region 15 in the Y axis direction in the second region 28. The length of the emitter region 12 in the Y axis direction may be the same or differ for/between the first region 26 and the second region 28. In another example, the length of one emitter region 12 in the Y axis direction in the first region 26 may be smaller than the length of one emitter region 12 in the Y axis direction in the second region 28. In this case, the length of the contact region 15 in the Y axis direction may be the same or differ for/between the first region 26 and the second region 28.

In this example, the mesa portion 60 overlapping the first region 26 is set as a mesa portion 60-a, and the mesa portion 60 not overlapping the first region 26 is set as a mesa portion 60-b. The mesa portion 60 overlapping both the first region 26 and the second region 28 may also be set as the mesa portion 60-a. A contact area ratio in the mesa portion 60-a may be the contact area ratio of the first region 26. A contact area ratio in the mesa portion 60-b may be the contact area ratio of the second region 28.

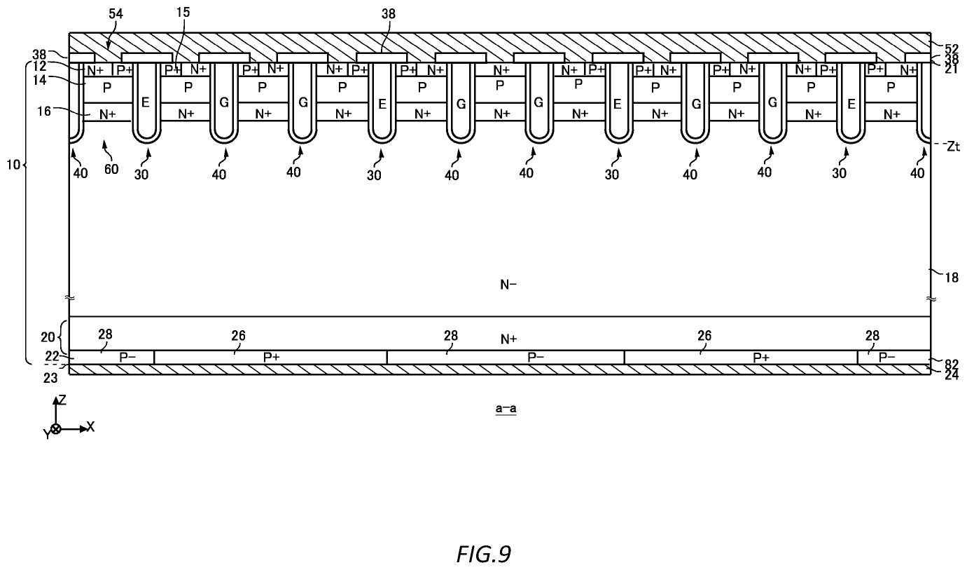

FIG. 9 illustrates a view showing another example of the cross section a-a. In this example, the arrangement of the contact regions 15 on the upper surface 21 of the semiconductor substrate 10 differs from that of the example shown in FIG. 7. Other structures are similar to those of the example shown in FIG. 7. The contact region 15 of this example is arranged next to the emitter region 12 in the X axis direction.

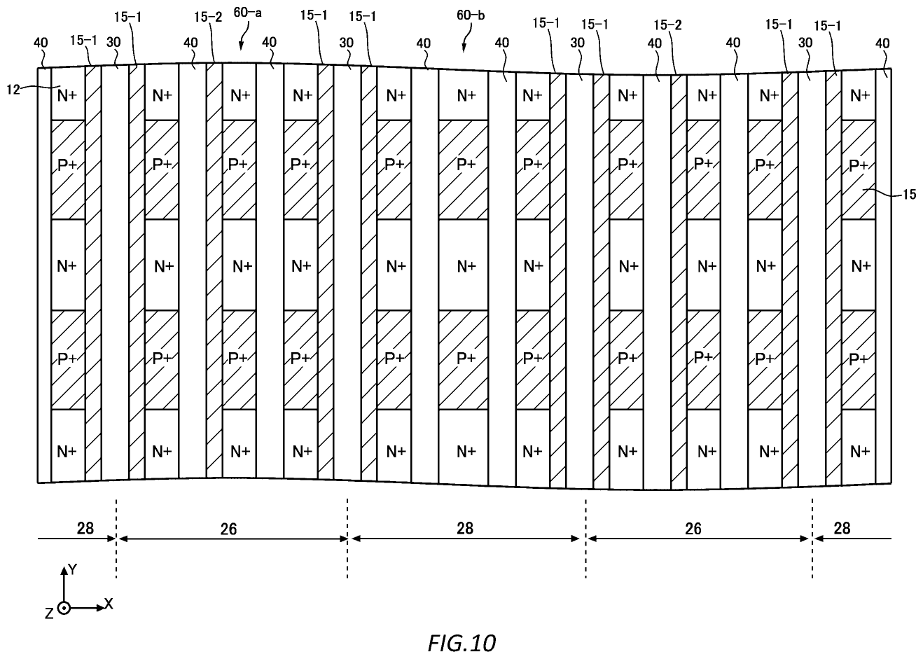

FIG. 10 illustrates a view showing an exemplary arrangement of the emitter regions 12 and the contact regions 15 in a top view. In FIG. 10, the contact regions 15 are hatched with diagonal lines. On the upper surface of each mesa portion 60 of this example, the contact region 15 in direct contact with the emitter region 12 in the X axis direction and the contact region 15 in direct contact with the emitter region 12 in the Y axis direction are arranged in a connected manner. Also in this example, the contact area ratio R1 of the first region 26 is higher than the contact area ratio R2 of the second region 28. Moreover, by arranging the contact region 15 in direct contact with the emitter region 12, a path for extracting holes implanted from the first region 26 to the emitter electrode 52 is formed next to the emitter region 12, so the resistance of the path can be lowered, and latch-up can be suppressed. The contact area ratio R1 may be 1.2 times or more, 1.5 times or more, or 2 times or more of the contact area ratio R2. The contact regions 15 and contact regions 15-1 and contact regions 15-2 hatched with diagonal lines may have the same doping concentration distribution.

The semiconductor device 100 may include the contact region 15-2 in contact with the gate trench portion 40 and the contact region 15-1 in contact with the dummy trench portion 30. In this example, the contact regions 15-1 are arranged on both sides of each dummy trench portion 30 in the X axis direction.

An area ratio of the contact regions 15-2 provided in the first region 26 (an area of the contact regions 15-2 with respect to an area of the first region 26) is higher than an area ratio of the contact regions 15-2 provided in the second region 28. In this example, one contact region 15-2 is provided with respect to at least one gate trench portion 40 in the first region 26, and the contact region 15-2 is not provided in the second region 28.

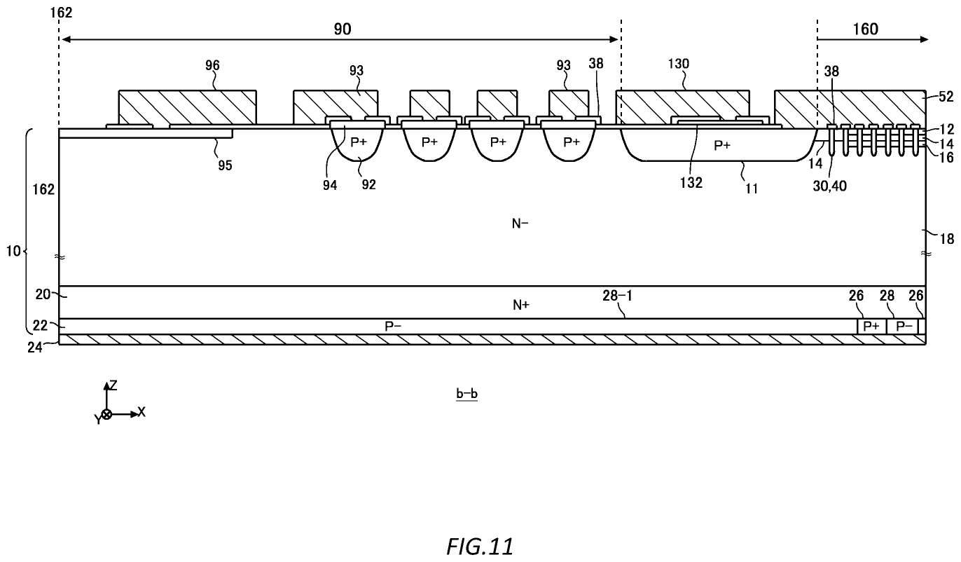

FIG. 11 illustrates a view showing an example of a cross section b-b in FIG. 1. The cross section b-b is an XZ plane that passes through the edge termination structure portion 90 and a part of the active portion 160 (the transistor portion 70). The edge termination structure portion 90 may include one or more guard rings 92. The edge termination structure portion 90 may include one or more field plates 93. The guard rings 92 are each a P+ type region provided in contact with the upper surface 21 of the semiconductor substrate 10. The guard rings 92 enclose the active portion 160. The field plates 93 are each a metal member arranged above the upper surface 21 of the semiconductor substrate 10. The interlayer dielectric film 38 may be provided between the field plates 93 and the semiconductor substrate 10. The field plates 93 and the guard rings 92 may or may not be electrically connected. In this example, the field plates 93 and the guard rings 92 are connected via a polysilicon wiring 94 provided on the upper surface of the semiconductor substrate 10.

On an outer side of the guard rings 92 and the field plates 93, a channel stopper 95 and an electrode 96 may be provided. The channel stopper 95 prevents a depletion layer extending from the active portion 160 from reaching the end side 162 of the semiconductor substrate 10. The channel stopper 95 is a P type or N type region having a higher concentration than the drift region 18. The electrode 96 is connected to the channel stopper 95. The same potential as the collector electrode 24 may be applied to the electrode 96.

The outer circumferential gate runner 130 is provided between the active portion 160 and the edge termination structure portion 90. A polysilicon gate runner 132 may be provided between the outer circumferential gate runner 130 and the semiconductor substrate 10. The well region 11 is provided below the outer circumferential gate runner 130 and the gate runner 132. The well region 11 may be connected to the emitter electrode 52. The well region 11 may be in contact with the base region 14.

The active portion 160 is provided with both the first region 26 and the second region 28. The edge termination structure portion 90 may be provided with the second region 28 and not be provided with the first region 26. By providing the second region 28 in the entire edge termination structure portion 90, the implantation efficiency of holes with respect to the edge termination structure portion 90 can be made small to thus improve a dynamic breakdown voltage of the edge termination structure portion 90. Accordingly, an overvoltage withstand capability (clamp withstand capability) of the semiconductor device 100 can be improved.

A second region 28-1 of the edge termination structure portion 90 may extend to below the well region 11. The second region 28-1 may overlap with the entire well region 11. In other words, the second region 28-1 may be provided and the first region 26 does not need to be provided at a position overlapping the well region 11. The second region 28-1 may extend to a position overlapping the emitter electrode 52. The second region 28-1 may extend to the active portion 160. In this example, an end portion of the well region 11 on the opposite side of the end side 162 is given as an end portion of the active portion 160. By extending the second region 28-1, it becomes easy to improve the breakdown voltage in the edge termination structure portion 90.

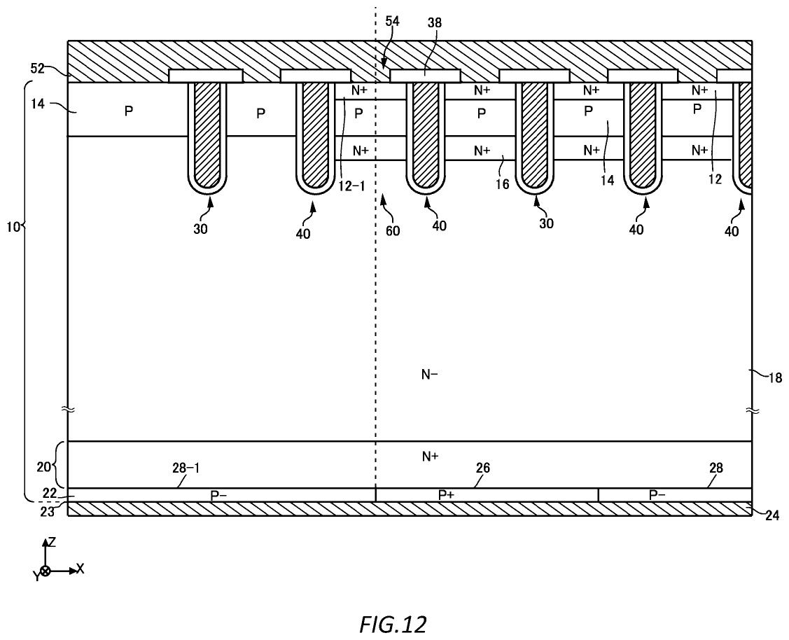

FIG. 12 illustrates a view showing an exemplary arrangement of the second region 28-1 in the active portion 160. FIG. 12 is an enlarged view showing a vicinity of the end portion of the second region 28-1 on the active portion 160 side. The second region 28-1 of this example is provided so as to extend to a position overlapping an emitter region 12-1 of the active portion 160. The emitter region 12-1 of this example is an emitter region 12 closest to the edge termination structure portion 90 in the X axis direction. An end portion of the second region 28-1 in the X axis direction may overlap with the emitter region 12-1. The end portion of the second region 28-1 in the X axis direction may be provided at a position overlapping the contact hole 54 of the mesa portion 60 provided with the emitter region 12-1. A boundary between the first region 26 and the second region 28-1 may be provided below the mesa portion 60. With the configuration as shown in FIGS. 11 and 12, the variation in characteristics of the transistor portion 70 can be suppressed and the turn-off loss can be reduced while improving the breakdown voltage of the edge termination structure portion 90.

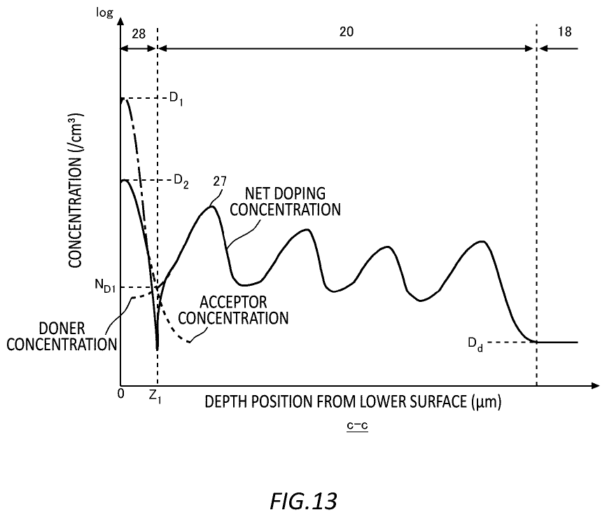

FIG. 13 illustrates a view showing an example of a net doping concentration distribution on a line c-c in FIG. 3. The line c-c passes through the second region 28, the buffer region 20, and a part of the drift region 18. The doping concentration of the buffer region 20 is higher than a doping concentration D_{d} of the drift region 18. The buffer region 20 of this example has one or more doping concentration peaks 27 arranged at different positions in the depth direction.

The doping concentration D₂ of the collector region in the second region 28 is higher than the doping concentration D_{d} of the drift region 18. The doping concentration D₁ of the collector region in the first region 26 may also be higher than the doping concentration D_{d} of the drift region 18. In FIG. 13, the doping concentration of the first region 26 is indicated by a dash-dot-dash line. The doping concentration D₁ may be 10 times or more, 50 times or more, or 100 times or more of the doping concentration D_{d}. Accordingly, a variation in the doping concentration D₁ can be suppressed.

A depth position of a PN junction portion between the second region 28 and the buffer region 20 is represented by Z₁. A donor concentration at the depth position Z₁ is represented by N_{D1}. The donor concentration is a concentration of the donor such as phosphorus or hydrogen that has been implanted for forming the buffer region 20. In FIG. 13, the donor and acceptor concentrations close to the depth position Z₁ are indicated by broken lines.

The doping concentration D₂ of the collector region in the second region 28 is higher than the donor concentration N_{D1} at the depth position Z₁. Accordingly, the second region 28 having a low concentration can be turned into the P type for sure. The doping concentration D₂ may be 5 times or more or 10 times or more of the donor concentration N_{D1}. The doping concentration D₂ may be higher than the doping concentration of the doping concentration peak 27. When the buffer region 20 has a plurality of doping concentration peaks 27, the doping concentration D₂ may be higher than the doping concentration of each of the plurality of doping concentration peaks 27.

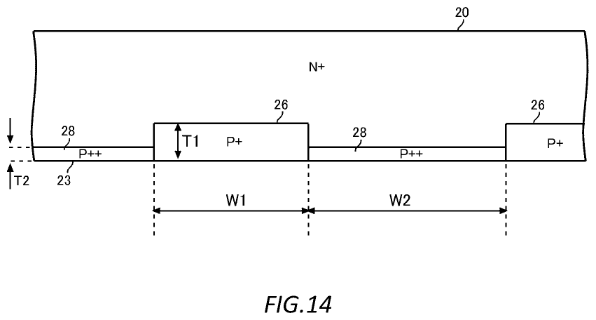

FIG. 14 illustrates a view showing another example of the first region 26 and the second region 28. In the examples of FIGS. 1 to 13, the examples where the doping concentration D₁ of the first region 26 and the doping concentration D₂ of the second region 28 are used to adjust the implantation efficiency have been described. In this example, a method of adjusting the implantation efficiency of the first region 26 and the second region 28 differs. Matters other than the method of adjusting the implantation efficiency of the first region 26 and the second region 28 are similar to those of any of the examples described in FIGS. 1 to 13. For example, the positions and ranges at/in which the first region 26 and the second region 28 are provided in a top view are similar to those of any of the examples described in FIGS. 1 to 13.

The thickness of the collector region 22 in the first region 26 is represented by T1. The thickness of the collector region 22 in the second region 28 is represented by T2. The thickness is a length in the depth direction (the Z axis direction) of the semiconductor substrate 10. In this example, the thickness T1 is larger than the thickness T2. As shown in Expression (1), by setting the thickness T1 to be larger than the thickness T2, the implantation efficiency of the first region 26 can be set to be higher than the implantation efficiency of the second region 28. The thickness T1 may be 2 times or more, 4 times or more, or 10 times or more of the thickness T2. The thickness T1 may be 20 times or less of the thickness T2. The thickness T1 may be 0.3 μm or more, 0.4 μm or more, or 0.5 μm or more. The thickness T2 may be 0.2 μm or less, 0.15 μm or less, or 0.1 μm or less.

The doping concentration D₁ in the first region 26 and the doping concentration D₂ in the second region 28 may be D₁>D₂ similar to the examples described in FIGS. 1 to 13, or may be the same.

Further, the concentration of the P type impurity in the second region 28 may be higher than the concentration of the P type impurity in the first region 26. The P type impurity implanted into the first region 26 may be activated by locally annealing the first region 26 by laser annealing. The second region 28 does not need to be subjected to laser annealing. A dose amount (ions/cm²) of the P type impurity with respect to the second region 28 may be larger than a dose amount of the P type impurity with respect to the first region 26. By setting the dose amount with respect to the second region 28 to be larger and not annealing the second region 28, the thickness T2 of the second region 28 can be made small while lowering the contact resistance between the second region 28 and the collector electrode 24. The concentration of the P type impurity in the second region 28 may be 2 times or more, 5 times or more, or 10 times or more of the concentration of the P type impurity in the first region 26. The doping concentration D₂ in the second region 28 may be higher than the doping concentration D₁ in the first region 26.

A distance between two first regions 26 (the width W2 of the second region 28 in this example) in a top view may be equal to or smaller than a diffusion length of holes as the minority carriers in the drift region 18. A diffusion length L_{P} is a distance that the carriers move until disappearing, and is given by the following expression.

L_{P}=√(D_{P}×τ_{P})

Note that D_{P} is a diffusion coefficient of holes, and τ_{P} is an average value of hole lifetimes. Accordingly, an influence of holes implanted from the second region 28 on an operation of the semiconductor device 100 can be suppressed. The distance between two first regions 26 may be 80% or less or 50% or less of the diffusion length L_{P}.

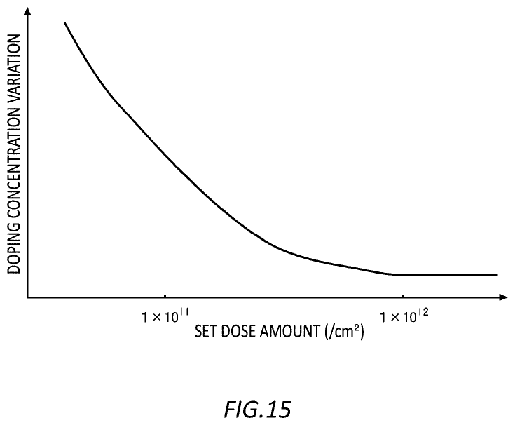

FIG. 15 illustrates a view showing a relationship between a dose amount setting value of the P type impurity implanted into the collector region 22 and a doping concentration variation of the collector region 22. The doping concentration of the collector region 22 is a value obtained after performing the implantation of the P type impurity and annealing. The doping concentration variation may be a standard deviation of doping concentrations in a plurality of semiconductor devices 100. Although the doping concentration variation is shown in the example of FIG. 15, the on-voltage of the semiconductor device 100 similarly varies.

Even when a certain dose amount is set, the doping concentration varies due to a variation in dose amount, a variation in annealing condition, and the like. A ratio of the variation increases as the dose amount setting value decreases. Thus, as shown in FIG. 15, the doping concentration variation tends to increase as the dose amount setting value decreases. In the example of FIG. 15, the doping concentration variation becomes substantially constant when the dose amount setting value exceeds 1×10¹²/cm².

The dose amount with respect to the first region 26 may be 1×10¹²/cm² or more. A value obtained by integrating a peak waveform of the doping concentration of the first region 26 in a range of full width at half maximum in the depth direction may be used as the dose amount of the first region 26. The dose amount with respect to the first region 26 may be 1×10¹³/cm² or more or 1×10¹⁴/cm² or more.

While the embodiments of the present invention have been described, the technical scope of the present invention is not limited to the above-described embodiments. It is apparent to persons skilled in the art that various alterations or improvements can be made to the above-described embodiments. It is also apparent from the description of the claims that embodiments added with such alterations or improvements can be included in the technical scope of the present invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A semiconductor device, comprising:
a semiconductor substrate which includes an upper surface and a lower surface and is provided with a drift region of a first conductivity type;
an emitter region of a first conductivity type, which is provided in contact with the upper surface of the semiconductor substrate and has a higher doping concentration than the drift region;
a base region of a second conductivity type, which is provided in contact with the emitter region; and
a collector region of a second conductivity type, which is provided between the drift region and the lower surface of the semiconductor substrate, wherein
the collector region includes a first region and a second region having a lower implantation efficiency of carriers with respect to the drift region than the first region, and
when an area of the first region and an area of the second region per unit area of the collector region in a top view are respectively represented by S₁ and S₂, the implantation efficiency of the first region is represented by η₁, and the implantation efficiency of the second region is represented by η₂, an average implantation efficiency η_{C} given by an expression below is 0.1 or more and 0.4 or less:
η_{C}=(S₁×η₁+S₂×η₂)/(S₁+S₂)

2. The semiconductor device according to claim 1, wherein
a doping concentration of the collector region in the first region is higher than a doping concentration of the collector region in the second region.

3. The semiconductor device according to claim 2, wherein
when the doping concentration of the collector region in the first region is represented by D₁ and the doping concentration of the collector region in the second region is represented by D₂, an average doping concentration D_{C} given by an expression below is 1×10¹⁵/cm³ or more and 1×10¹⁸/cm³ or less:
D_{C}=(S₁×D₁+S₂×D₂)/(S₁+S₂).

4. The semiconductor device according to claim 3, wherein
the doping concentration of the collector region in the second region is 1×10¹⁵/cm³ or more and 1×10¹⁷/cm³ or less.

5. The semiconductor device according to claim 3, wherein
the doping concentration of the collector region in the second region is higher than a doping concentration of the drift region.

6. The semiconductor device according to claim 3, further comprising:
a buffer region which is formed between the second region and the drift region and has a higher doping concentration than the drift region,
wherein the doping concentration of the collector region in the second region is higher than a donor concentration at a PN junction portion between the second region and the buffer region.

7. The semiconductor device according to claim 3, wherein
the doping concentration D₁ of the collector region in the first region is higher than the average doping concentration D_{C},
the average doping concentration D_{C} is higher than the doping concentration D₂ of the collector region in the second region,
a ratio α of the area S₂ of the second region to the area S of the first region is given by an expression below:
α=S₂/S₁,
a ratio β is given by an expression below including the doping concentration D₁ of the collector region in the first region:
β=(D₁/D_{C}−1)+D₂/(D_{C}−D₂), and
the ratio α is equal to or larger than the ratio β.

8. The semiconductor device according to claim 1, wherein
the collector region in the first region is thicker in a depth direction of the semiconductor substrate than the collector region in the second region.

9. The semiconductor device according to claim 8, wherein
a concentration of a second conductivity type impurity of the second region is higher than a concentration of a second conductivity type impurity of the first region.

10. The semiconductor device according to claim 8, wherein
a distance between two of the first regions in the top view is equal to or smaller than a diffusion length of minority carriers in the drift region.

11. The semiconductor device according to claim 1, comprising:
an active portion including the emitter region and the base region;
a well region of a second conductivity type, which encloses the active portion in the top view and is provided in contact with the upper surface of the semiconductor substrate; and
an edge termination structure portion arranged between the well region and end sides of the semiconductor substrate, wherein
the active portion is provided with both the first region and the second region, and
the edge termination structure portion is provided with the second region and is not provided with the first region.

12. The semiconductor device according to claim 11, wherein
the second region is provided and the first region is not provided at a position overlapping the well region.

13. The semiconductor device according to claim 11, wherein
the second region of the edge termination structure portion is provided so as to extend to a position overlapping the emitter region of the active portion.

14. The semiconductor device according to claim 1, further comprising:
a gate trench portion which is provided from the upper surface of the semiconductor substrate to the drift region and is in contact with the emitter region and the base region,
wherein the first region is provided at a position overlapping the gate trench portion.

15. The semiconductor device according to claim 1, further comprising:
a contact region which is provided in contact with the upper surface of the semiconductor substrate and has a higher doping concentration than the base region, wherein
a contact area ratio of the first region is higher than a contact area ratio of the second region, and
the contact area ratio is a ratio of an area of the contact region exposed on the upper surface of the semiconductor substrate to a unit area.

16. A semiconductor device, comprising:
a semiconductor substrate which includes an upper surface and a lower surface and is provided with a drift region of a first conductivity type;
an emitter region of a first conductivity type, which is provided between the drift region and the upper surface of the semiconductor substrate and has a higher doping concentration than the drift region;
a base region of a second conductivity type, which is provided in contact with the emitter region; and
a collector region of a second conductivity type, which is provided between the drift region and the lower surface of the semiconductor substrate, wherein
the collector region includes a first region and a second region having a lower implantation efficiency of carriers with respect to the drift region than the first region, and
when an area of the first region and an area of the second region per unit area of the collector region in a top view are respectively represented by S₁ and S₂, a doping concentration of the collector region in the first region is represented by D₁, and a doping concentration of the collector region in the second region is represented by D₂, an average doping concentration D_{C} given by an expression below is 1×10¹⁵/cm³ or more and 1×10¹⁸/cm³ or less:
D_{C}=(S₁×D₁+S₂×D₂)/(S₁+S₂).

17. The semiconductor device according to claim 2, comprising:
an active portion including the emitter region and the base region;
a well region of a second conductivity type, which encloses the active portion in the top view and is provided in contact with the upper surface of the semiconductor substrate; and
an edge termination structure portion arranged between the well region and end sides of the semiconductor substrate, wherein
the active portion is provided with both the first region and the second region, and
the edge termination structure portion is provided with the second region and is not provided with the first region.

18. The semiconductor device according to claim 3, comprising:
an active portion including the emitter region and the base region;
a well region of a second conductivity type, which encloses the active portion in the top view and is provided in contact with the upper surface of the semiconductor substrate; and
an edge termination structure portion arranged between the well region and end sides of the semiconductor substrate, wherein
the active portion is provided with both the first region and the second region, and
the edge termination structure portion is provided with the second region and is not provided with the first region.

19. The semiconductor device according to claim 4, comprising:
an active portion including the emitter region and the base region;
a well region of a second conductivity type, which encloses the active portion in the top view and is provided in contact with the upper surface of the semiconductor substrate; and
an edge termination structure portion arranged between the well region and end sides of the semiconductor substrate, wherein
the active portion is provided with both the first region and the second region, and
the edge termination structure portion is provided with the second region and is not provided with the first region.

20. The semiconductor device according to claim 5, comprising:
an active portion including the emitter region and the base region;
a well region of a second conductivity type, which encloses the active portion in the top view and is provided in contact with the upper surface of the semiconductor substrate; and
an edge termination structure portion arranged between the well region and end sides of the semiconductor substrate, wherein
the active portion is provided with both the first region and the second region, and
the edge termination structure portion is provided with the second region and is not provided with the first region.
